(19) United States
(12) Patent Application Publication
(10) Pub. No.: US 2008/0198557 A1
(43) Pub. Date: Aug. 21, 2008

(54) HEAT-DISSIPATING MODULE

(75) Inventors: Choo Soo Lim, Amphur Muang (TH); Piya Theprin, Amphur Muang (TH); Suksit Khammukchik, Amphur Muang (TH)

Correspondence Address: MADSON & AUSTIN, 15 WEST SOUTH TEMPLE, SUITE 900, SALT LAKE CITY, UT, 84101, US

(73) Assignee: Delta Electronics (Thailand) Public Company, Limited, Amphur Muang (TH)

(21) Appl. No.: 11/739,524

(22) Filed: Apr. 24, 2007

(30) Foreign Application Priority Data
Feb. 16, 2007 (TW) 096106087

(51) Int. Cl. H05K 7/20

(52) U.S. Cl. 361/719

(57) ABSTRACT

A heat-dissipating module includes a circuit board, an electronic component and a heat-dissipating device. The circuit board includes at least a hollow portion and at least a contact portion. The electronic component includes at least a pin connected to the contact portion of the circuit board. The heat-dissipating device is embedded into the hollow portion of the circuit board and interposed between the electronic component and an inner surface of the covering body, thereby providing a heat-transfer path along the heat-conducting device to the covering body to remove the heat generate from the electronic component

### FIELD OF THE INVENTION

The present invention relates to a heat-dissipating module, and more particularly to a heat-dissipating module for providing a heat-transfer path of removing heat from an electronic component.

### BACKGROUND OF THE INVENTION

With increasing integration of integrated circuits, electronic devices such as power adapters and power supply apparatuses are developed toward minimization. As the volume of the electronic device is decreased, the problem associated with heat dissipation becomes more serious. Take a power adapter for example. The conventional power adapter comprises a casing defining a closed space for accommodating a printed circuit board. When the power adapter operates, the electronic components on the printed circuit board thereof may generate energy in the form of heat, which is readily accumulated in the closed space and usually difficult to dissipate away. If the power adapter fails to transfer enough heat to ambient air, the elevated operating temperature may result in damage of the electronic components, a breakdown of the whole power adapter or reduced power conversion efficiency.

For increasing the heat-dissipating efficiency, the electronic components generating energy in the form of heat with relatively higher power are disposed beside or attached on the inner wall of the casing of the power adapter, thereby increasing the heat transfer area due to the casing.

Referring to FIG. 1, a schematic cross-sectional view of a heat-dissipating module of a conventional power adapter is illustrated. The power adapter 1 comprises several electronic components 10, which are mounted on a circuit board 14. For neat drawings, however, only a high power electronic component 10, e.g. a transistor, is shown in the drawing. A first surface of the heat sink 11 is attached on a back surface of the electronic component 10. A second surface of the heat sink 11 is in contact with the inner wall of the casing 12. By means of a fixing element 13 such as a screw or a clamp, the electronic component 10 and the heat sink 11 are fastened onto the inner wall of the casing 12. Meanwhile, the heat transfer area responsible for removing the heat generated from the electronic component 10 is increased because the heat is transferred to the ambient air through casing 12. For facilitating fixing the electronic component 10 on the circuit board 14, the pins 15 of the electronic component 10 are inserted into corresponding contact portions on the circuit board 14. Since the electronic component 10 is located in the vicinity of the casing 12, the electronic component 10 is usually mounted on the edge of the circuit board 14. Under this circumstance, the layout configuration of the trace pattern on the circuit board 14 is complicated, and the electronic component 10 is readily suffered from electromagnetic interference (EMI). Moreover, since the electronic component 10 is mounted on the edge of the circuit board 14, shear stresses may be exerted on the contact portions between the pins 15 and the circuit board 14 if the power adapter 1 is suffered from a drop or a strong impact, and the pins 15 may be fractured. Moreover, since the electronic component 10 is mounted on the circuit board 14 along the height direction of the casing 12, the thickness of the power adapter 1 fails to be further reduced.

Referring to FIG. 2, a schematic cross-sectional view of another heat-dissipating module is illustrated. The power adapter 1 of FIG. 2 is substantially identical to that of FIG. 1, except that a heat-dissipating device 16 is interposed between the heat sink 11 and the inner wall of the casing 12. The heat-dissipating device 16 is fixed on the circuit board 14. Likewise, since the electronic component 10 is mounted on the circuit board 14 along the height direction of the casing 12, the thickness of the power adapter 1 fails to be further reduced. In addition, it is difficult to firmly secure the heat-dissipating device 16 on the circuit board 14.

For solving the above problems, another heat-dissipating module as shown in FIG. 3 was developed. The power adapter 2 of FIG. 3 comprises several electronic components 20. For neat drawings, however, only a high power electronic component 20, e.g. a transistor, is shown in the drawing. The pins 25 of the electronic component 20 are bent at a right angle and inserted into corresponding contact portions on a circuit board 24. A first surface of the heat sink 21 is attached on a back surface of the electronic component 20. However, the second surface of the heat sink 21 is in contact with the inner surface at the bottom of the casing 22. Under this circumstance, the electronic component 20 is mounted on the circuit board 24 along the length direction of the casing 22, and thus the thickness of the power adapter 2 may be further reduced. Please refer to FIG. 3 again. The circuit board 24 further includes a hollow portion 23 corresponding to the electronic component 20. Typically, the size of the hollow portion 23 is slightly larger than that of the electronic component 20 in order to facilitate mounting the electronic component 20 on the circuit board 24 and attaching the combination of the heat sink 21 and the electronic component 20 on the inner surface at the bottom of the casing 22. In a case that more electronic component 20 are mounted on the circuit board 24, the number of the hollow portions 23 are increased and the layout configuration of the trace pattern on the circuit board 24 becomes more complicated. If the power adapter 2 is suffered from a drop or a strong impact, shear stresses may be exerted on the contact portions between the pins 25 and the circuit board 24 and thus the pins 25 may be fractured.

Referring to FIG. 4(a), a schematic cross-sectional view of another heat-dissipating module is illustrated. The power adapter 3 of FIG. 4(a) comprises several electronic components 30. For neat drawings, however, only a high power electronic component 30, e.g. a transistor, is shown in the drawing. The pins 35 of the electronic component 30 are bent at a right angle and inserted into corresponding contact portions on a circuit board 34. The circuit board 34 further includes plural via holes 33 corresponding to the electronic component 30. After these via holes 33 are drilled in the circuit board 34, metallization are implemented on the sidewalls of these via holes 33 by an electroplating technology to deposit a metallic layer 331 thereon, as is shown in FIG. 4(b). Please refer to FIG. 4(a) again. A first surface of a heat sink 31 is attached on a back surface of the electronic component 30. A second surface of a heat sink 31 is in contact with the upper surface of the circuit board 34 to cover these via holes 33. A heat-dissipating pad 36 is interposed between the lower surface of the circuit board 34 and the inner surface of the casing 32. When the power adapter 3 operates, the heat generated from the electronic component 30 are conducted to the casing 32 through these via holes 33 and the heat-dissipating pad 36 and then transferred to the ambient air. Generally, except for the metallic layer 331, a majority of the via hole 33 is occupied by poor thermally conductive medium, i.e. air. As a consequence, the heat-dissipating efficiency of such a heat-dissipating module is not satisfied. Moreover, the process of fabricating these via holes 33 is labor-intensive and not cost-effective.

In views of the above-described disadvantages resulted from the conventional method, the applicant keeps on carving unflaggingly to develop a heat-dissipating module according to the present invention through wholehearted experience and research.

### SUMMARY OF THE INVENTION

It is an object of the present invention to provide a heat-dissipating module for providing a heat-transfer path along a heat-conducting device to the covering body so as to enhance heat-dissipating efficiency.

Another object of the present invention is to provide another heat-dissipating module having reduced number of hollow portions so as to simplify the layout configuration of the trace pattern on the circuit board.

In accordance with an aspect of the present invention, there is provided a heat-dissipating module of an electronic device. The heat-dissipating module comprises a circuit board, an electronic component and a heat-dissipating device. The circuit board includes at least a hollow portion and at least a contact portion. The electronic component includes at least a pin connected to the contact portion of the circuit board. The heat-dissipating device is embedded into the hollow portion of the circuit board and interposed between the electronic component and an inner surface of the covering body, thereby providing a heat-transfer path along the heat-conducting device to the covering body to remove the heat generate from the electronic component.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view of a heat-dissipating module of a conventional power adapter;

FIG. 2 is a schematic cross-sectional view of another heat-dissipating module of a conventional power adapter;

FIG. 3 is a schematic cross-sectional view of another heat-dissipating module of a conventional power adapter;

FIG. 4(a) is a schematic cross-sectional view of another heat-dissipating module of a conventional power adapter;

FIG. 4(b) is a schematic partial enlarged cross-sectional view of the heat-dissipating module of FIG. 4(a) to indicate a metallic layer formed on the inner wall of a via hole;

FIG. 5(a) is a schematic cross-sectional view of a heat-dissipating module of a power adapter according to a first preferred embodiment of the present invention;

FIG. 5(b) is a schematic partial exploded view of the heat-dissipating module of FIG. 5(a);

FIGS. 6(a), 6(b) and 6(c) schematically illustrate three examples of the heat-conducting devices used in the present invention; and

FIG. 7 is a schematic cross-sectional view of a heat-dissipating module of a power adapter according to a second preferred embodiment of the present invention.

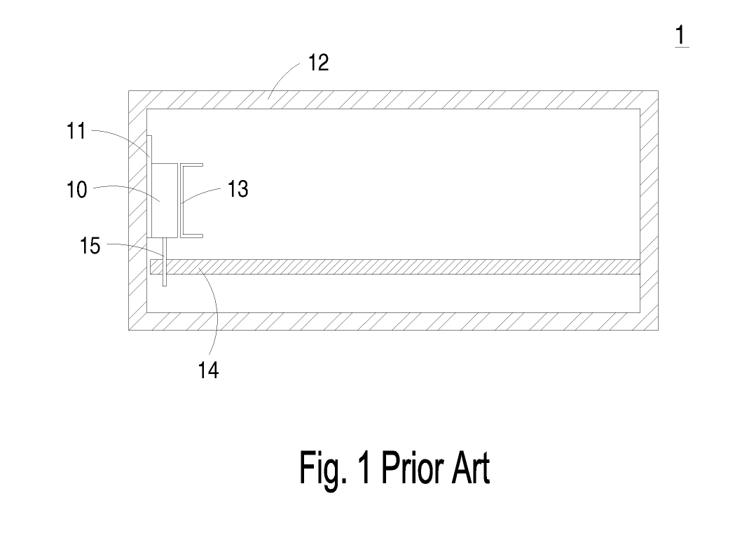

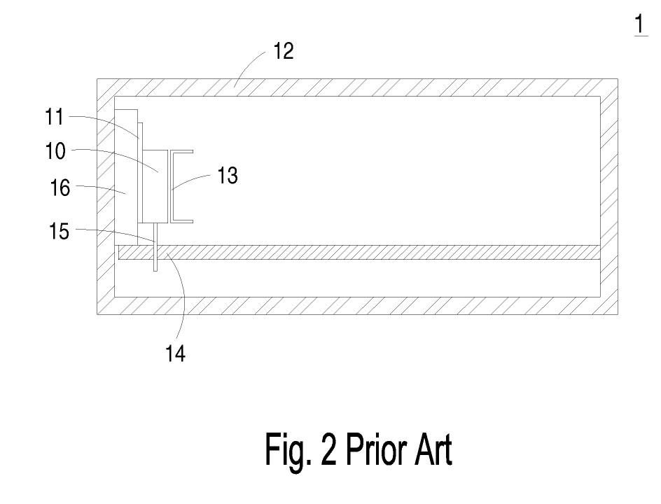

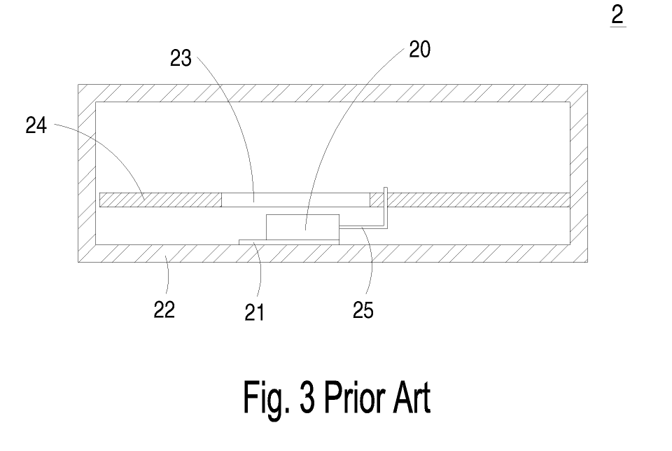

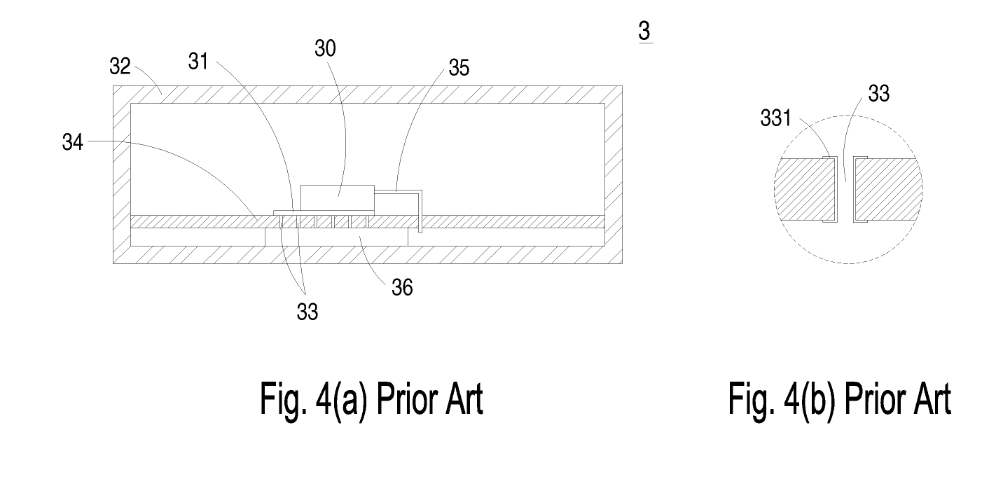

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

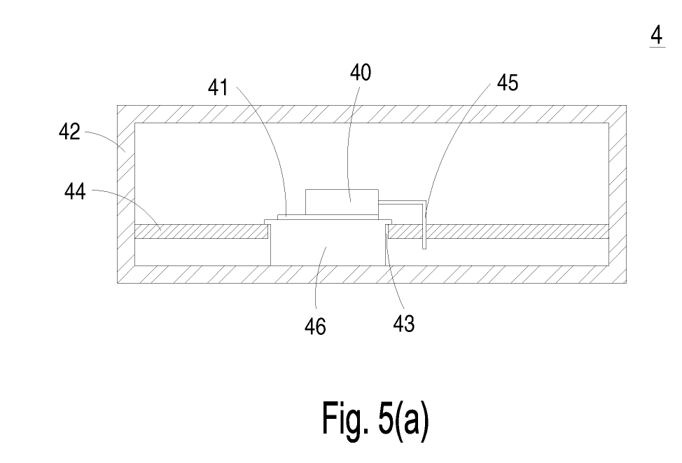

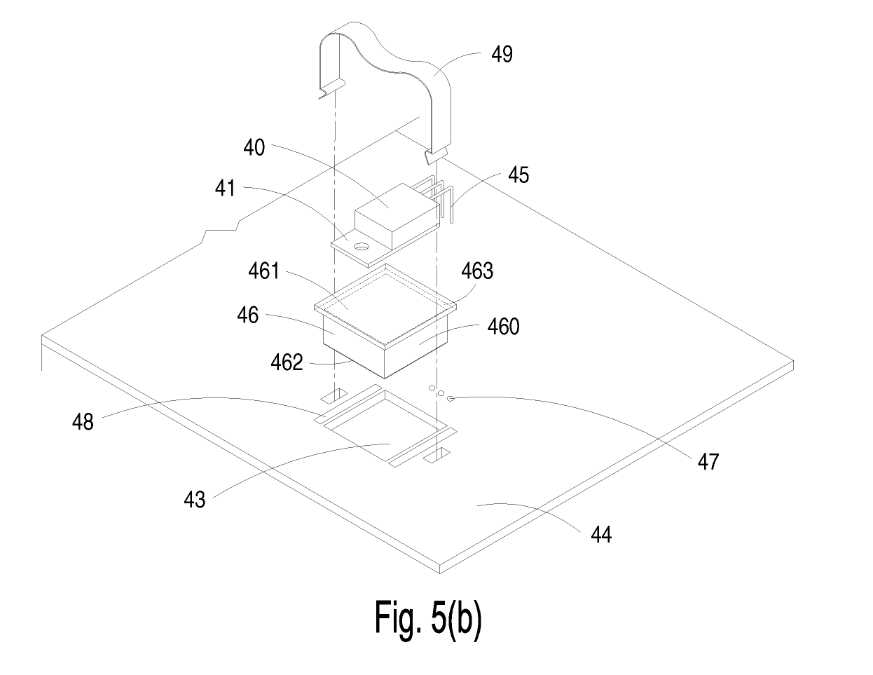

FIG. 5(a) is a schematic cross-sectional view of a heat-dissipating module of a power adapter according to a preferred embodiment of the present invention. FIG. 5(b) is a schematic partial exploded view of the heat-dissipating module of FIG. 5(a). As shown in FIGS. 5(a) and 5(b), the power adapter 4 comprises several electronic components 40. For neat drawings, however, only a high power electronic component 40, e.g. a transistor, is shown in the drawing. The pins 45 of the electronic component 40 are bent at a right angle and coupled to corresponding contact portions on a circuit board 44. In this embodiment, the pins 45 are in-line package pins or surface mount device (SMD) pins so that the pins 45 of the electronic component 40 can be connected to the contact portions of the circuit board 44 by through-hole technology or surface mount technology. A first surface of a heat sink 41 is attached on a back surface of the electronic component 40. The circuit board 44 further includes a hollow portion 43 corresponding to the electronic component 40 and plural contact portions 47 corresponding to the pins 45. A heat-conducting device 46 is interposed between the second surface of the heat sink 41 and the inner surface of the covering body 42. Alternatively, the electronic component 40 is an encapsulating package and the heat sink is dispensed with. Under this circumstance, the heat-conducting device 46 is interposed between the electronic component 40 and the inner surface of the casing 42.

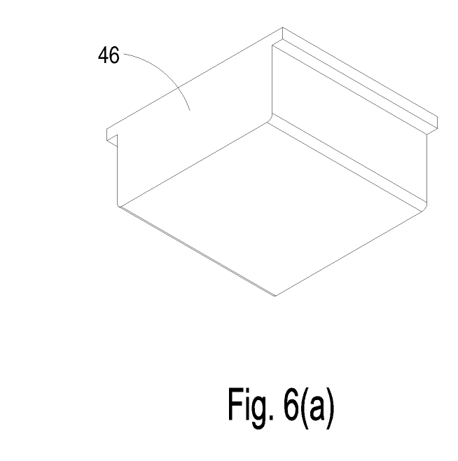

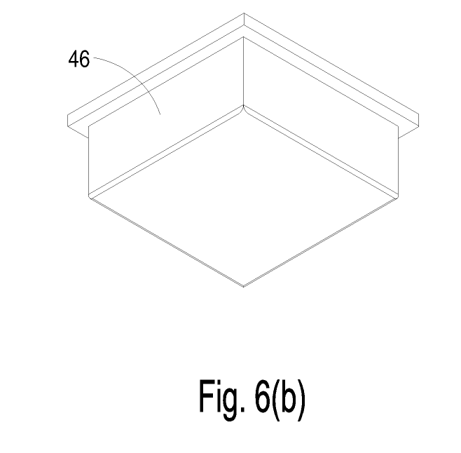

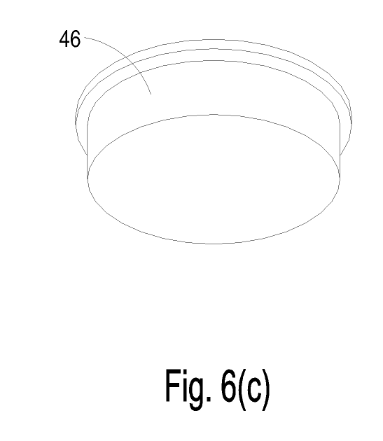

The heat-conducting device 46 is made of a metallic material having high thermal conductivity, for example copper or aluminum. In some embodiments, the heat-conducting device 46 is a polygonal or cylindrical post, as can be seen in FIGS. 6(a), 6(b) and 6(c). Please refer to FIGS. 5(a) and 5(b) again. The heat-conducting device 46 comprises a main body 460, a first surface 461, a second surface 462 and a protrusion edge 463. The protrusion edge 463 is extended from the first surface 461 or the second surface 462. Optionally, at least a welding region 48 is formed on the periphery of the hollow portion 43 of the circuit board 44. The size of the hollow portion 43 is substantially identical to the cross-section of the main body 460 of the heat-conducting device 46. As a consequence, the heat-conducting device 46 is tight-fitted into the hollow portion 43 of the circuit board 44. For facilitating fixing the heat-conducting device 46 on the circuit board 44, the protrusion edge 463 of the heat-conducting device 46 is welded on the welding region 48 of the circuit board 44. After the heat-conducting device 46 is embedded into the hollow portion 43 of the circuit board 44, the second surface 462 of the heat-conducting device 46 is attached onto the inner surface of the covering body 42. In this embodiment, the covering body 42 is a casing of the power adapter 4 or a metal shielding member within the casing.

In some embodiments, the pins 45 of the electronic component 40 are welded onto the contact portions 47 of the circuit board 44. By means of a fixing element 49 such as a screw or a clamp, the electronic component 40 and the heat sink 41 are fastened onto the first surface 461 of the heat-conducting device 46, as is shown in FIG. 5(b). In such manner, the heat generated from the electronic component 40 are conducted to the covering body 42 through the heat-conducting device 46 and then transferred to the ambient air. Optionally, a heat-dissipating pad (not shown) is interposed between the heat sink 41 and the heat-conducting device 46. By means of a fixing element such as a screw or a clamp, the electronic component 40 and the heat-dissipating pad is fastened onto the first surface 461 of the heat-conducting device 46.

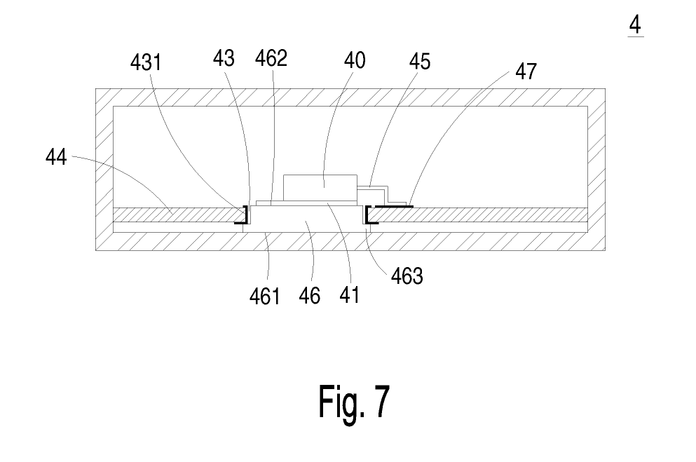

A further embodiment of a heat-dissipating module is illustrated in FIG. 7. In this embodiment, most components are identical to those of FIG. 5, and are not redundantly described herein. In addition, the heat-conducting device 46 is embedded into the hollow portion 43 of the circuit board 44 from the bottom of the circuit board 44, so that the heat-conducting device 46 is tight-fitted into the hollow portion 43 of the circuit board 44. As a result, the protrusion edge 463 of the heat-conducting device 46 is sustained against the periphery of the hollow portion 43 at the lower surface of the circuit board 44. That is, the protrusion edge 463 of the heat-conducting device 46 and the electronic component 40 are disposed on opposite sides of the circuit board 44. After the heat-conducting device 46 is embedded into the hollow portion 43 of the circuit board 44, the first surface 461 of the heat-conducting device 46 is attached onto the inner surface of the covering body 42. In this embodiment, the covering body 42 is a casing of the power adapter 4 or a metal shielding member within the casing.

Please refer to FIG. 7 again. A metallic layer 431 is formed on the sidewall of the hollow portion 43. By welding the heat-conducting device 46 onto the metallic layer 431, the heat-conducting device 46 is firmly fixed onto the circuit board 44. The pins 45 of the electronic component 40 are bent at a right angle and coupled to corresponding contact portions 47 on the circuit board 44. The contact portions 47 are via holes or contact pads, and the pins 45 are in-line package pins or surface mount device (SMD) pins. In some embodiments, the pins 45 of the electronic component 40 are welded onto the contact portions 47 of the circuit board 44. By means of a fixing element (not shown) such as a screw or a clamp, the electronic component 40 and the heat sink 41 are fastened onto the second surface 462 of the heat-conducting device 46. In such manner, the heat generated from the electronic component 40 are conducted to the covering body 42 through the heat-conducting device 46 and then transferred to the ambient air. Optionally, a heat-dissipating pad (not shown) is interposed between the heat sink 41 and the heat-conducting device 46. By means of a fixing element such as a screw or a clamp, the electronic component 40 and the heat-dissipating pad is fastened onto the second surface 462 of the heat-conducting device 46.

In the above embodiments, the heat-conducting device 46 is welded onto the welding region 48 (FIG. 5) or welded onto the metallic layer 431 (FIG. 7) according to a wave solder process or a direct re-flow process.

From the above description, the heat-dissipating module of the present invention provides a heat-transfer path along a heat-conducting device to the covering body, so that the heat-dissipating efficiency is enhanced. In addition, the process of mounting the electronic component is simplified. Since the size of the hollow portion is substantially identical to the cross-section of the main body of the heat-conducting device, the number of the hollow portions is reduced when compared to conventional heat-dissipating module. As a consequence, the layout configuration of the trace pattern on the circuit board is simplified.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat-dissipating module of an electronic device, said electronic device comprising a covering body, said heat-dissipating module comprising:
a circuit board including at least a hollow portion and at least a contact portion;
an electronic component including at least a pin connected to said contact portion of said circuit board; and
a heat-dissipating device embedded into said hollow portion of said circuit board and interposed between said electronic component and an inner surface of said covering body, thereby providing a heat-transfer path along said heat-conducting device to the covering body to remove the heat generate from said electronic component.

2. The heat-dissipating module according to claim 1 wherein said electronic component is a transistor.

3. The heat-dissipating module according to claim 1 further including a heat sink between a back surface of said electronic component and said heat-dissipating device.

4. The heat-dissipating module according to claim 1 wherein said heat-dissipating device is made of copper or aluminum.

5. The heat-dissipating module according to claim 1 wherein said heat-dissipating device is a polygonal or cylindrical post.

6. The heat-dissipating module according to claim 1 wherein said heat-dissipating device includes:
a first surface attached onto said electronic component;
a second surface; and
a protrusion edge extended from said first surface.

7. The heat-dissipating module according to claim 6 wherein said circuit board further includes a welding region at the periphery of said hollow portion, wherein said protrusion edge of said heat-dissipating device is connected to said welding region.

8. The heat-dissipating module according to claim 6 further including a fixing element for fastening said electronic component onto said first surface of said heat-conducting device.

9. The heat-dissipating module according to claim 6 wherein said second surface of said heat-conducting device is attached onto said inner surface of said covering body.

10. The heat-dissipating module according to claim 6 wherein said protrusion edge of said heat-conducting device and said electronic component are disposed on the same side of said circuit board.

11. The heat-dissipating module according to claim 1 wherein said covering body is a casing of said electronic device or a metal shielding member within said casing.

12. The heat-dissipating module according to claim 1 wherein a metallic layer is formed on a sidewall of said hollow portion, and said heat-conducting device is welded onto said metallic layer.

13. The heat-dissipating module according to claim 1 wherein said heat-dissipating device includes:
a first surface;
a second surface attached onto said electronic component; and
a protrusion edge extended from said first surface.

14. The heat-dissipating module according to claim 13 further including a fixing element for fastening said electronic component onto said second surface of said heat-conducting device.

15. The heat-dissipating module according to claim 13 wherein said first surface of said heat-conducting device is attached onto said inner surface of said covering body.

16. The heat-dissipating module according to claim 13 wherein said protrusion edge of said heat-conducting device and said electronic component are disposed on opposite sides of said circuit board.

17. The heat-dissipating module according to claim 1 wherein the size of said hollow portion of said circuit board is substantially equal to the cross-section of a main body of said heat-conducting device, so that said heat-conducting device is tight-fitted into said hollow portion of said circuit board.

18. The heat-dissipating module according to claim 1 wherein said heat-conducting device is fixed in said hollow portion of said circuit board and said pin of said electronic component is fixed on said contact portion of said circuit board by a welding process.

19. The heat-dissipating module according to claim 18 wherein said welding process is a wave solder process or a direct re-flow process.

20. The heat-dissipating module according to claim 1 wherein said pin of said electronic component is connected to said contact portion of said circuit board by one of surface mount technology and through-hole technology.
